(19) United States
(12) Patent Application Publication
(10) Pub. No.: US 2025/0374668 A1
(43) Pub. Date: Dec. 4, 2025

(54) SEMICONDUCTOR DEVICE

(71) Applicant: Samsung Electronics Co., Ltd., Suwon-si (KR)

(72) Inventors: Choonghwan KIM, Suwon-si (KR); Donghoon HWANG, Suwon-si (KR); Hyojin KIM, Suwon-si (KR); Byungho MOON, Suwon-si (KR); Jaeho JEON, Suwon-si (KR)

(73) Assignee: Samsung Electronics Co., Ltd., Suwon-si (KR)

(21) Appl. No.: 19/223,197

(22) Filed: May 30, 2025

(30) Foreign Application Priority Data
Jun. 3, 2024 (KR) 10-2024-0072550

(51) Int. Cl. H10D 84/85; H10D 30/00; H10D 30/01; H10D 62/10; H10D 62/13; H10D 64/23; H10D 84/01

(52) U.S. Cl. CPC H10D 84/856; H10D 30/502; H10D 62/121; H10D 62/151; H10D 64/251; H10D 84/851; H10D 30/0191; H10D 84/017; H10D 84/0186

(57) ABSTRACT

Provided is a semiconductor device that includes a first active pattern and a second active pattern on a substrate, the first active pattern spaced apart from the second active pattern in a first direction, and extending in a second direction, the second direction being different from the first direction, a lower channel pattern and a lower source/drain pattern on the first active pattern and alternately arranged in the second direction, an upper channel pattern on the lower channel pattern, and an upper source/drain pattern on the lower source/drain pattern, a gate pattern on first active pattern, the lower channel pattern, and the upper channel pattern, and a first active contact connected to the lower source/drain pattern, and a second active contact connected to the upper source/drain pattern.

### CROSS-REFERENCE TO RELATED APPLICATION

This application claims priority to and the benefit of Korean Patent Application No. 10-2024-0072550 filed in the Korean Intellectual Property Office on Jun. 3, 2024, the entire contents of which are incorporated herein by reference.

### BACKGROUND

Some example embodiments of the present disclosure relate to semiconductor devices, for example, three-dimensional semiconductor devices.

A semiconductor is a material that is categorized between a conductor and an insulator and refers to a material that conducts electricity under certain conditions. Various semiconductor devices can be manufactured using these semiconductor materials, for example, memory devices, etc., and may be used in various electronic devices.

As the electronics industry continues to develop, demands for improved characteristics of semiconductor devices increases accordingly. For example, demands for higher reliability, higher speed, and/or multifunctionality of semiconductor devices continues to increase. In order to meet these desired characteristics, structures within semiconductor devices continue to increase in complexity and integration.

### SUMMARY

Some example embodiments of the present disclosure provide a semiconductor device, and a method of forming a semiconductor device, including filling a metal contact without leaving a residue or empty space when forming a first active contact thereby reducing or preventing damage to the lower source/drain pattern and the first etch stop layer. Furthermore, the method of forming the semiconductor device may reduce or prevent the lower source/drain pattern from being damaged, and may have improved capacitance as the area where the lower source/drain pattern overlaps with the gate pattern is reduced.

A semiconductor device according to some example embodiments includes a first active pattern and a second active pattern on a substrate, the first active pattern spaced apart from the second active pattern in a first direction, and extending in a second direction, the second direction being different from the first direction, a lower channel pattern and a lower source/drain pattern on the first active pattern and alternately arranged in the second direction, an upper channel pattern on the lower channel pattern, and an upper source/drain pattern on the lower source/drain pattern, a gate pattern on first active pattern, the lower channel pattern, and the upper channel pattern, and a first active contact connected to the lower source/drain pattern, and a second active contact connected to the upper source/drain pattern. The lower source/drain pattern includes an asymmetric shape on a first side and an asymmetric shape on a second side, the first side and the second side being opposite to each other in the first direction, and the first active contact is connected to a first side of the lower source/drain pattern in the first direction.

A semiconductor device according to some example embodiments includes a first active pattern and a second active pattern on a substrate, the first active pattern spaced apart from the second active pattern in a first direction, and extending in a second direction, the second direction being different from the first direction, a lower channel pattern and a lower source/drain pattern on the first active pattern and alternately arranged in the second direction, an upper channel pattern on the lower channel pattern, and an upper source/drain pattern on the lower source/drain pattern, a gate pattern on the first active pattern, the lower channel pattern, and the upper channel pattern, and a first active contact connected to the lower source/drain pattern, and a second active contact connected to the upper source/drain pattern. The first active contact includes a lower contact portion connected to a first side of the lower source/drain pattern in the first direction, and the lower contact portion extending in the first direction, an upper contact portion connected to the lower contact portion, and the upper contact portion extending in a third direction, the third direction being different from the first direction and the second direction, and a width of the lower contact portion in the third direction at a point closer to the lower source/drain pattern in the first direction is greater than a width of the lower contact portion in the third direction at a point further from the lower source/drain pattern in the first direction.

A semiconductor device according to some example embodiments includes a first active pattern on a substrate, the first active pattern spaced apart from the second active pattern in a first direction, and extending in a second direction, the second direction being different from the first direction, a lower channel pattern and a lower source/drain pattern on the first active pattern and alternately arranged in the second direction, an upper channel pattern on the lower channel pattern, and an upper source/drain pattern on the lower source/drain pattern, a gate pattern on the first active pattern, the lower channel pattern, and the upper channel pattern, a first active contact connected to the lower source/drain pattern, and a second active contact connected to the upper source/drain pattern. The lower source/drain pattern includes an asymmetric shape on a first side and a second side, the first side and the second side being opposite each other in the first direction, the first active contact includes a lower contact portion connected to the first side of the lower source/drain pattern in the first direction, and the lower contact portion extending in the first direction, an upper contact portion connected to the lower contact portion, and the upper contact portion extending in a third direction, the third direction being different from the first direction and the second direction, and a width of the lower contact portion in the third direction at a point closer to the lower source/drain pattern in the first direction is greater than a width of the lower contact portion in the third direction at a point further from the lower source/drain pattern in the first direction.

The semiconductor device and method of forming the semiconductor device according to some example embodiments may fill the metal contact without leaving a residue or empty space when forming the first active contact which may reduce or prevent damage to the lower source/drain pattern and the first etch stop layer Furthermore, the method may reduce or prevent damage to the lower source/drain pattern and the first etch stop layer, and may improve capacitance as the area where the lower source/drain pattern overlaps with the gate pattern is reduced.

### BRIEF DESCRIPTION OF THE DRAWINGS

FIG. 1 is a conceptual view for explaining a logic cell of a semiconductor device according to a comparative example embodiment.

FIG. 2 is a conceptual view for explaining a logic cell of a semiconductor device according to some example embodiments.

FIG. 3 is a plan view showing a semiconductor device according to some

example embodiments.

FIG. 4 is a cross-sectional view taken along line A-A′ in FIG. 3.

FIG. 5 is a cross-sectional view taken along line B-B′ of FIG. 3.

FIG. 6 is a cross-sectional view taken along line B-B′ of FIG. 3.

FIG. 7 is an enlarged cross-sectional view of portion P of FIG. 5.

FIGS. 8 to 29 are cross-sectional views showing a method of manufacturing a semiconductor device according to a process sequence of some example embodiments.

### DETAILED DESCRIPTION OF THE EMBODIMENTS

Hereinafter, some example embodiments will be described more fully hereinafter with reference to the accompanying drawings, in which some example embodiments of the disclosure are shown. As those skilled in the art would realize, the described example embodiments may be modified in various different ways, all without departing from the spirit or scope of the present disclosure.

The drawings and description are to be regarded as illustrative in nature and not restrictive. Like reference numerals designate like elements throughout the specification.

The size and thickness of each constituent element as shown in the drawings are randomly indicated for better understanding and ease of description, and this disclosure is not necessarily limited to as shown. In the drawings, the thickness of layers, regions, etc., are exaggerated for clarity. In addition, in the drawings, for better understanding and ease of description, the thickness of some layers and areas is exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means being disposed on or below the object portion, and does not necessarily mean being disposed on the upper side of the object portion based on a gravitational direction.

In addition, unless explicitly described to the contrary, the word “comprise,” and variations such as “comprises” or “comprising”, will be understood to imply the inclusion of stated elements but not the exclusion of any other elements.

In addition, in this specification, the phrase “on a plane” means viewing a target portion from the top, and the phrase “on a cross-section” means viewing a cross-section formed by vertically cutting a target portion from the side.

In addition, throughout the specification, two directions parallel to and intersecting the upper surface of the substrate are defined as the first direction D1 and the second direction D2, respectively, and the direction perpendicular to the upper surface of the substrate is described as the third direction D3. For example, the first direction D1 and the second direction D2 may be perpendicular to each other.

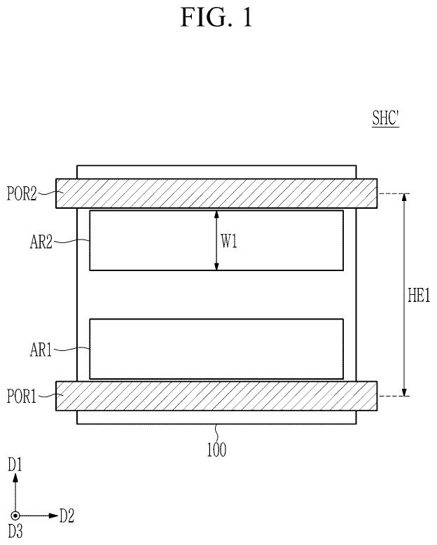

FIG. 1 is a conceptual view for explaining a logic cell of a semiconductor device according to a comparative example embodiment. In some example embodiments, FIG. 1 shows a single height cell SHC′, which is a logic cell of a two-dimensional semiconductor device.

Referring to FIG. 1, a first power wiring POR1 and a second power wiring POR2 may be located on the substrate 100. A drain voltage (VDD), that is, a power voltage, may be applied to either the first power wiring POR1 or the second power wiring POR2. A source voltage, which may be a ground, may be applied to the other one of the first power wiring POR1 and the second power wiring POR2. For example, a source voltage may be applied to the first power wiring POR1 and a drain voltage may be applied to the second power wiring POR2.

A single height cell SHC′ may be located between the first power wiring POR1 and the second power wiring POR2. The single height cell SHC′ may include a first active region AR1 and a second active region AR2. One of the first active region AR1 and the second active region AR2 may be a PMOSFET region, and the other one of the first active region AR1 and the second active region AR2 may be an NMOSFET region. For example, the first active region AR1 may be an NMOSFET region, and the second active region AR2 may be a PMOSFET region. In other words, the single height cell SHC′ may have a CMOS structure between the first power wiring POR1 and the second power wiring POR2.

The semiconductor device shown in FIG. 1 is a two-dimensional semiconductor device, and transistors in a front end of line (FEOL) layer may be arranged two-dimensionally. For example, the NMOSFETs in the first active region AR1 and the PMOSFETs in the second active region AR2 may be formed to be spaced apart from each other in the first direction D1.

Each of the first active region AR1 and the second active region AR2 may have a first width W1 in the first direction D1. The length of the single height cell SHC′ in the first direction D1 may be defined as the first distance HE1. The first distance HE1 may be equal or substantially equal to the distance (e.g., pitch) between the first power wiring POR1 and the second power wiring POR2.

A single height cell SHC′ can constitute one logic cell. In this specification, a logic cell may refer to a logic element (e.g., AND, OR, XOR, XNOR, or inverter) that performs a specific function. That is, a logic cell may include transistors for configuring a logic element and wirings configured to connect the transistors to each other.

Since the single height cell SHC′ includes a two-dimensional semiconductor device, the first active region AR1 and the second active region AR2 are not overlapped in the third direction D3 and are spaced apart from each other in the first direction D1. Accordingly, the first distance HE1 of the single height cell SHC′ should be defined to encompass both the first and second active regions AR1 and AR2 spaced apart from each other in the first direction D1. As a result, the first distance HE1 of the single height cell SHC′ cannot help but become relatively large. In other words, an area of the single height cell SHC′ may be relatively large.

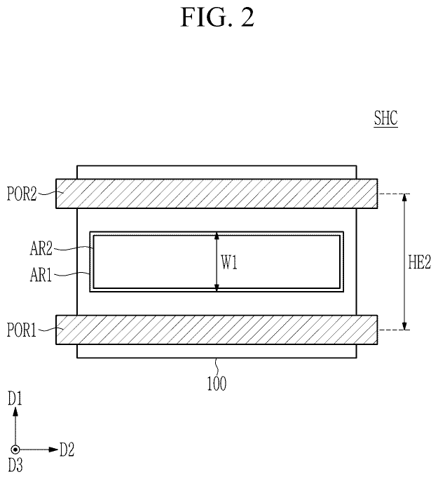

FIG. 2 is a conceptual view for explaining a logic cell of a semiconductor device according to some example embodiments. In some example embodiments, FIG. 2 shows a single height cell SHC including a three-dimensional semiconductor device (e.g., a stacked transistor).

Referring to FIG. 2, a first power wiring POR1 and a second power wiring POR2 may be located on the substrate 100. A single height cell SHC may be located between the first power wiring POR1 and the second power wiring POR2.

The single height cell SHC may include a first active region AR1 and a second active region AR2. One of the first active region AR1 and the second active region AR2 may be a PMOSFET region, and the other one of the first active region AR1 and the second active region AR2 may be an NMOSFET region.

The semiconductor device shown in FIG. 2 is a three-dimensional semiconductor device, and transistors of the FEOL layer may be stacked in the third direction D3. The first active region AR1 may be located on the substrate 100 as a bottom tier, and the second active region AR2 may be stacked on the first active region AR1 as a top tier. For example, NMOSFETs in the first active region AR1 may be located on the substrate 100, and PMOSFETs in the second active region AR2 may be stacked on the NMOSFETs. The first active region AR1 and the second active region AR2 may be spaced apart from each other in the third direction D3.

Each of the first active region AR1 and the second active region AR2 may have a first width W1 in the first direction D1. A length of the single height cell SHC in the first direction D1 may be defined as a second distance HE2.

Since the single height cell SHC includes a three-dimensional semiconductor device, that is, a stacked transistor, the first active region AR1 and the second active region AR2 may be overlapped in the third direction D3. Accordingly, the second distance HE2 of the single height cell SHC may have a size that encompasses one first width W1 described above. As a result, the second distance HE2 of the single height cell SHC may be smaller than the first distance HE1 of the single height cell SHC′ of FIG. 1 described above. In other words, the area of a single height cell SHC may be relatively small. The integration of semiconductor devices may be improved by reducing an area of the logic cell.

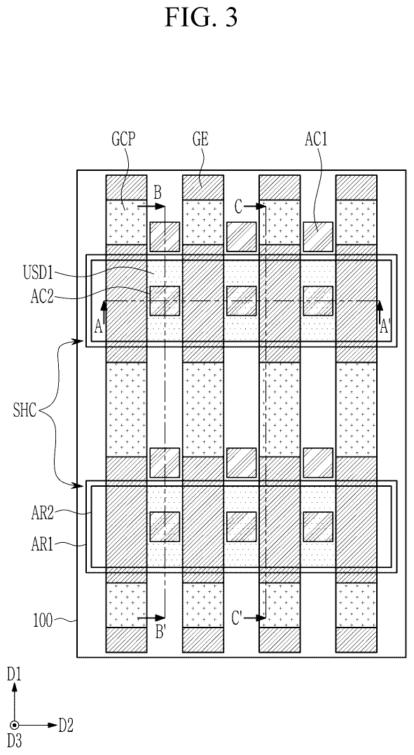

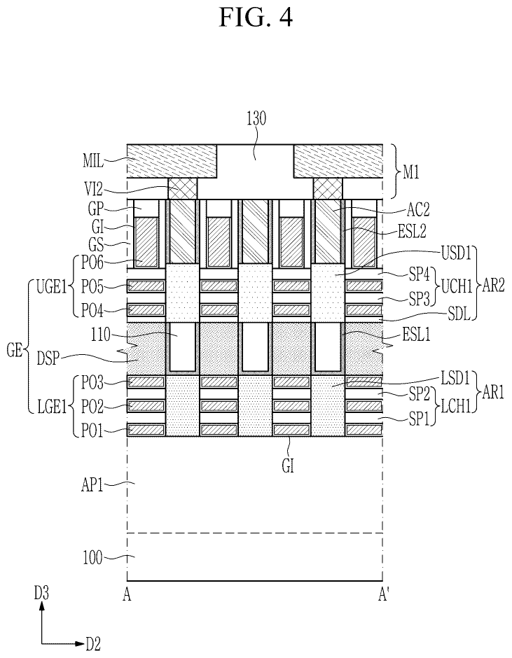

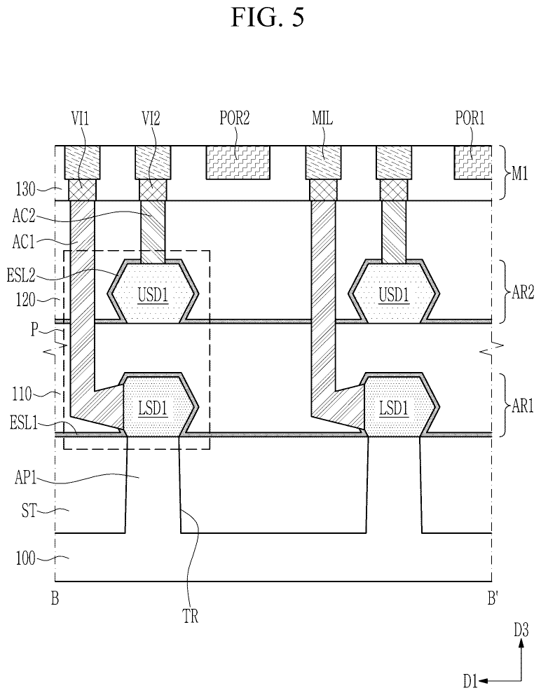

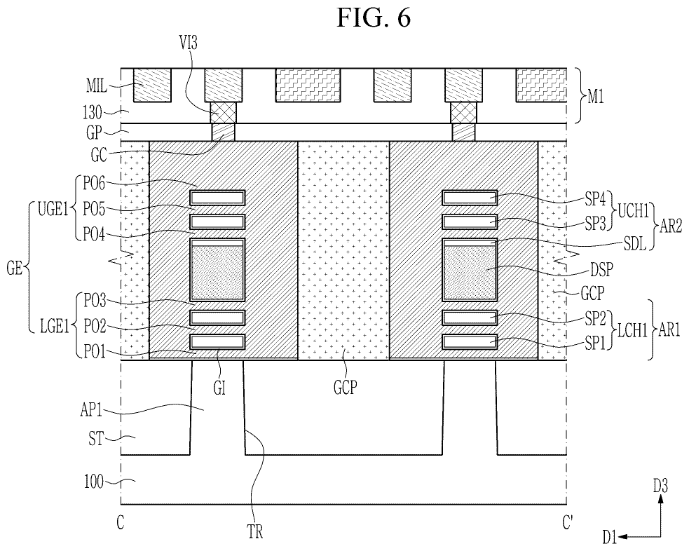

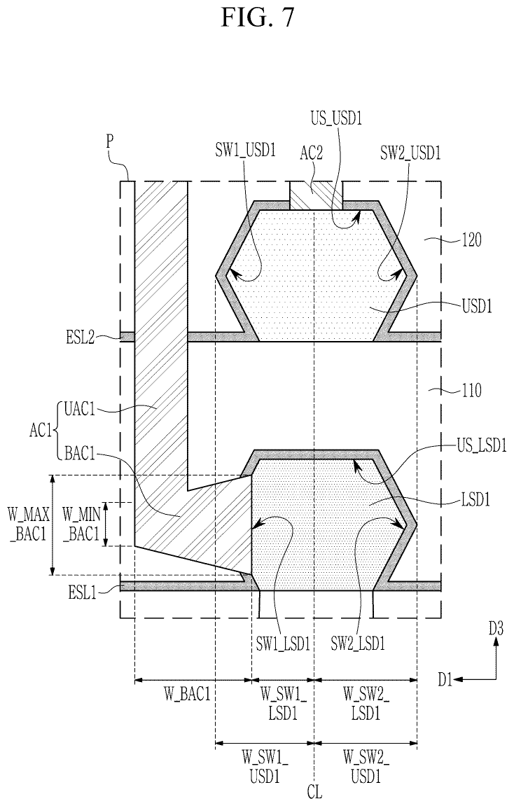

FIG. 3 is a plan view showing a semiconductor device according to some example embodiments. FIG. 4 is a cross-sectional view taken along line A-A′ in FIG. 3. FIG. 5 is a cross-sectional view taken along line B-B′ in FIG. 3. FIG. 6 is a cross-sectional view taken along line B-B′ of FIG. 3. FIG. 7 is an enlarged cross-sectional view of portion P of FIG. 5. The semiconductor device shown in FIGS. 3 to 7 represents an example of the single height cell SHC of FIG. 2.

Referring to FIGS. 3 to 7, the substrate 100 may be a semiconductor substrate including silicon, germanium, silicon germanium, etc., or a compound semiconductor substrate. In some example embodiments, the substrate 100 may be a silicon substrate. However, example embodiments are not limited thereto.

In some example embodiments, a cell region where logic cells constituting a logic circuit are disposed may be located in the first region on the substrate 100. For example, single height cells SHC of FIG. 2 may be located in the first region. The single height cells SHCs may be spaced apart from each other in the first direction D1.

Meanwhile, although not shown in FIGS. 3 to 7, a peripheral region where transistors constituting a processor core or an I/O terminal are disposed may be located in the second region on the substrate 100. In other words, the second region may be a core/peripheral region. In some example embodiments, the second region may include a long gate transistor (or long channel transistor) with a relatively long gate length (i.e., channel length). The transistor in the second region may be operated at a higher power than the transistor in the first region. For example, the transistor in the first region may be a single gate SG device, and the transistor in the second region may be an extra gate EG device.

Hereinafter, with reference to FIGS. 3 to 7, the three-dimensional transistor located in the first region will be described.

A single height cell SHC, which is a logic cell, may include a first active region AR1 and a second active region AR2 sequentially stacked on the substrate 100. One of the first and second active regions AR1 and AR2 may be a PMOSFET region, and the other of the first and second active regions AR1 and AR2 may be an NMOSFET region. The first active region AR1 may be located in the bottom tier of the FEOL layer, and the second active region AR2 may be located in the top tier of the FEOL layer. The NMOSFET and PMOSFET of the first and second active regions AR1 and AR2 may be stacked in the third direction D3 to form a three-dimensional stacked transistor. For example, the first active region AR1 may be a PMOSFET area, and the second active region AR2 may be an NMOSFET region.

The first active pattern AP1 may be defined by the trench TR located on the upper portion of the substrate 100. The first active pattern AP1 is a portion of the substrate 100 and may be a vertically protruding portion. In plan view, the first active pattern AP1 may have a bar shape that is spaced apart in the first direction D1 and extends in the second direction D2. The first and second active regions AR1 and AR2 may be sequentially stacked on the first active pattern AP1.

The device isolation layer ST may fill the trench TR. In some example embodiments, the device isolation layer ST may include silicon oxide. However, example embodiments are not limited thereto. The upper surface of the device isolation layer ST may be coplanar or substantially coplanar with the upper surface of the first active pattern AP1 or may be lower. The device isolation layer ST may not cover the lower channel pattern LCH1 and upper channel pattern UCH1, which will be described later.

A first active region AR1 including a lower channel pattern LCH1 and a lower source/drain pattern LSD1 may be located on the first active pattern AP1. The lower channel pattern LCH1 may be interposed between a pair of lower source/drain patterns LSD1. The lower channel pattern LCH1 may connect a pair of lower source/drain patterns LSD1 to each other. For example, the lower channel pattern LCH1 and the lower source/drain pattern LSD1 may be alternately arranged in the second direction D2.

The lower channel pattern LCH1 may include a first semiconductor pattern SP1 and a second semiconductor pattern SP2 that are stacked and spaced apart from each other in the third direction D3. Each of the first and second semiconductor patterns SP1 and SP2 may include silicon (Si), germanium (Ge), or silicon germanium (SiGe). However, example embodiments are not limited thereto. In some example embodiments, each of the first and second semiconductor patterns SP1 and SP2 may include crystalline silicon.

The lower source/drain pattern LSD1 may be located on the upper surface of the first active pattern AP1. The lower source/drain pattern LSD1 may be an epitaxial pattern formed through a selective epitaxial growth (SEG) process. For example, the upper surface of the lower source/drain pattern LSD1 may be higher than the upper surface of the second semiconductor pattern SP2 of the lower channel pattern LCH1.

The lower source/drain pattern LSD1 may be doped with impurities to have a first conductivity type. The first conductivity type may be N-type or P-type. In some example embodiments, the first conductivity type may be P-type. The lower source/drain pattern LSD1 may include silicon (Si) or silicon germanium (SiGe). However, example embodiments are not limited thereto.

The lower source/drain pattern LSD1 may have an asymmetric shape with a first side SW1_LSD1 and a second side SW2_LSD1 located on both sides in the first direction D1. In some example embodiments, in a cross-sectional view (e.g., FIGS. 5 and 7) of the lower source/drain pattern LSD1 cut in the first direction D1 and the third direction D3, the lower source/drain pattern LSD1 may have an asymmetric shape in which the first side SW1_LSD1 and the second side SW2_LSD1 are centered around the virtual central axis CL extending in the third direction D3.

Here, the cross-sectional view of the lower source/drain pattern LSD1 may be obtained by cutting in the first direction D1 and the third direction D3 at the midpoint of the second direction D2 of any one of the lower source/drain patterns LSD1, for example, FIGS. 5 and 7. In addition, the virtual central axis CL may be an axis extending in the third direction D3 while perpendicularly bisecting a line segment in contact with the lower surface of the source/drain pattern LSD1 and the first active pattern AP1, in cross-sectional view (e.g., FIGS. 5 and 7) of the lower source/drain pattern LSD1 cut in the first direction D1 and the third direction D3.

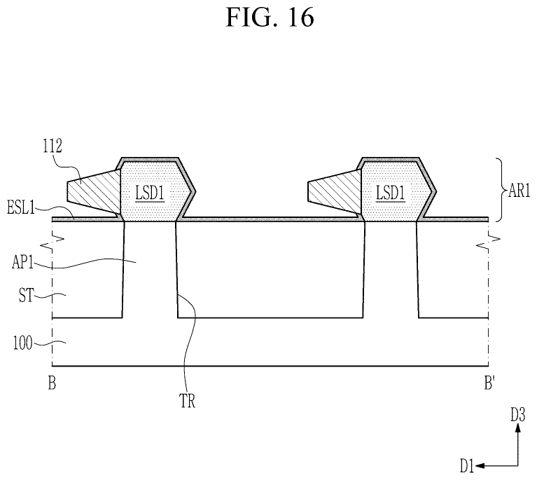

As described later, when forming a dummy contact (112 in FIG. 16, described later) to form the first active contact AC1, one side of the lower source/drain pattern LSD1, for example, the first side SW1_LSD1, is etched, and a dummy contact 112 is formed on the first side SW1_LSD1 of the lower source/drain pattern LSD1 using a lateral epitaxial growth (EPI lateral growth) process.

In other words, after forming a dummy contact extending long in the first direction D1 on the lower source/drain pattern LSD1 and forming an upper source/drain pattern USD1 on the dummy contact, the first active contact AC1 is not formed by removing the dummy contact and filling the empty space with metal. In this case, as the dummy contact extends long in the first direction D1, the first etch stop layer ESL1 covering the lower source/drain pattern LSD1 may be damaged when the dummy contact is formed, and when a dummy contact is removed, residue may remain, and it may be difficult to completely fill the shape of the removed dummy contact with metal.

On the other hand, in the case that the first side SW1_LSD1 of the lower source/drain pattern LSD1 is etched and the dummy contact 112 is formed using a lateral epitaxial growth process, when forming the first active contact AC1, metal can be filled without leaving any residue and no empty space, and damage to the lower source/drain pattern LSD1 and the first etch stop layer ESL1, which will be described later, may be reduced or prevented.

As the first side SW1_LSD1 of the lower source/drain pattern LSD1 is etched, the lower source/drain pattern LSD1 may have an asymmetric shape with a first side SW1_LSD1 and a second side SW2_LSD1 located on both sides in the first direction D1, and the first active contact AC1 may be connected to the first side SW1_LSD1 of the lower source/drain pattern LSD1. In this case, capacitance may be improved as the area where the lower source/drain pattern LSD1 is overlapped with the gate pattern GE in the second direction D2 decreases.

In some example embodiments, in a cross-sectional view of the lower source/drain pattern LSD1 cut in the first direction D1 and the third direction D3 (e.g., FIGS. 5 and 7), a first distance W_SW1_LSD1 of the lower source/drain pattern LSD1 to the first side SW1_LSD1 may be smaller than the second distance W_SW2_LSD1 to the second side SW2_LSD1.

Here, the first distance W_SW1_LSD1 to the first side SW1_LSD1 of the lower source/drain pattern LSD1 may be defined as the longest distance among the distances in the first direction D1 from the virtual central axis CL to the first side SW1_LSD1. For example, the first distance W_SW1_LSD1 to the first side SW1_LSD1 of the lower source/drain pattern LSD1 may be the distance to the surface in contact with the lower contact portion BAC1 of the first active contact AC1, which will be described later, and may be the distance in the first direction D1 from the center point of the third direction D3 of the lower source/drain pattern LSD1 to the first side SW1_LSD1.

The second distance W_SW2_LSD1 to the second side SW2_LSD1 of the lower source/drain pattern LSD1 may be defined as the longest distance among the distances in the first direction D1 from the virtual central axis CL to the second side SW2_LSD1. For example, the second distance W_SW2_LSD1 to the second side SW2_LSD1 of the lower source/drain pattern LSD1 may be the distance in the first direction D1 from the center point in the third direction D3 of the lower source/drain pattern LSD1 to the second side SW2_LSD1.

In some example embodiments, in a cross-sectional view of the lower source/drain pattern LSD1 cut in the first direction D1 and the third direction D3 (e.g., FIGS. 5 and 7), the first side SW1_LSD1 of the lower source/drain pattern LSD1 may have a flat shape. In other words, the first side SW1_LSD1 of the lower source/drain pattern LSD1 may not have a convex or concave shape toward the outside of the lower source/drain pattern LSD1 in the first direction D1. As described above, when forming the dummy contact 112, the first side SW1_LSD1 of the lower source/drain pattern LSD1 is etched, and thus the first side SW1_LSD1 of the lower source/drain pattern LSD1 has a flat shape. The flat surface of the first side SW1_LSD1 may contact the lower contact portion BAC1 of the first active contact AC1.

The second side SW2_LSD1 of the lower source/drain pattern LSD1 may have a convex shape toward the outside of the lower source/drain pattern LSD1. In other words, the second side SW2_LSD1 of the lower source/drain pattern LSD1 may have a convex shape in the first direction D1 toward the first interlayer insulating film 110.

Since the second side SW2_LSD1 of the lower source/drain pattern LSD1 is not connected to the first active contact AC1, the second side SW2_LSD1 of the lower source/drain pattern LSD1 is not etched to form the dummy contact 112, and thus the second side surface SW2_LSD1 of the lower source/drain pattern LSD1 may have a convex shape toward the outside of the lower source/drain pattern LSD1 in its original shape formed according to the selective epitaxial growth method.

The first etch stop layer ESL1 may be located on the lower source/drain pattern LSD1. In some example embodiments, the first etch stop layer ESL1 may cover the lower source/drain pattern LSD1.

The first etch stop layer ESL1 may cover the upper surface and the second side surface SW2_LSD1 of the lower source/drain pattern LSD1. The first etch stop layer ESL1 may not be located between the lower source/drain pattern LSD1 and the first active contact AC1. The first etch stop layer ESL1 may cover at least a portion of the first side surface SW1_LSD1 of the lower source/drain pattern LSD1. In some example embodiments, the first active contact AC1 is connected to the middle region in the third direction D3 of the first side SW1_LSD1 of the lower source/drain pattern LSD1, and the first etch stop layer ESL1 may cover the upper or lower region of the first side SW1_LSD1 of the lower source/drain pattern LSD1 that is not connected to the first active contact AC1.

The first interlayer insulating film 110 may be located on the first etch stop layer ESL1. The first interlayer insulating film 110 may cover the lower source/drain pattern LSD1.

A second interlayer insulating film 120 and a second active region AR2 may be located on the first interlayer insulating film 110. The second active region AR2 may include an upper channel pattern UCH1 and an upper source/drain pattern USD1.

The upper channel pattern UCH1 may be located on the lower channel pattern LCH1. The upper source/drain pattern USD1 may be located on the lower source/drain pattern LSD1. In other words, the upper channel pattern UCH1 may be overlapped with the lower channel pattern LCH1 in the third direction D3. The upper source/drain pattern USD1 may be overlapped with the lower source/drain pattern LSD1 in the third direction D3. The upper channel pattern UCH1 may be interposed between a pair of upper source/drain patterns USD1. The upper channel pattern UCH1 may connect a pair of upper source/drain patterns USD1 to each other. For example, the upper channel pattern UCH1 and the upper source/drain pattern USD1 may be alternately arranged in the second direction D2.

The upper channel pattern UCH1 may include a third semiconductor pattern SP3 and a fourth semiconductor pattern SP4 that are stacked and spaced apart from each other in the third direction D3. The third and fourth semiconductor patterns SP3 and SP4 of the upper channel pattern UCH1 include the same semiconductor material as the first and second semiconductor patterns SP1 and SP2 of the lower channel pattern LCH1 described above.

At least one dummy channel pattern DSP may be interposed between the lower channel pattern LCH1 and the upper channel pattern UCH1 above it. A seed layer SDL may be interposed between the dummy channel pattern DSP and the upper channel pattern UCH1.

The dummy channel pattern DSP may be spaced apart from the lower source/drain pattern LSD1 and the upper source/drain pattern USD1. That is, the dummy channel pattern DSP may not be connected to any source/drain pattern. The dummy channel pattern DSP may include a semiconductor material such as silicon (Si), germanium (Ge), or silicon germanium (SiGe), or may include a silicon-based insulating material such as a silicon oxide film or a silicon nitride film. However, example embodiments are not limited thereto. In some example embodiments, the dummy channel pattern DSP may include a silicon-based insulating material.

The upper source/drain pattern USD1 may be located on the upper surface of the first interlayer insulating film 110. The upper source/drain pattern USD1 may be an epitaxial pattern formed through a selective epitaxial growth (SEG) process. However, example embodiments are not limited thereto. For example, the upper surface of the upper source/drain pattern USD1 may be higher than the upper surface of the fourth semiconductor pattern SP4 of the upper channel pattern UCH1.

The upper source/drain pattern USD1 may be doped with impurities to have a second conductivity type. The second conductivity type may be different from the first conductivity type of the lower source/drain pattern LSD1. In some example embodiments, the second conductivity type may be N-type. The upper source/drain pattern USD1 may include silicon germanium (SiGe) or silicon (Si). However, example embodiments are not limited thereto.

The upper source/drain pattern USD1 may have a symmetrical shape with a first side SW1_USD1 and a second side SW2_USD1 located on both sides in the first direction D1. In some example embodiments, in a cross-sectional view of the upper source/drain pattern USD1 cut in the first direction D1 and the third direction D3 (e.g., FIGS. 5 and 7), the upper source/drain pattern USD1 may have a symmetrical shape in which the first side SW1_USD1 and the second side SW2_USD1 are centered around the virtual central axis CL extending in the third direction D3.

Here, the cross-sectional view of the upper source/drain pattern USD1 may be obtained by cutting in the first direction D1 and the third direction D3 at the midpoint of the second direction D2 of one of the upper source/drain patterns USD1, and may be, for example, FIGS. 5 and 7. In addition, in a cross-sectional view of the upper source/drain pattern USD1 cut in the first direction D1 and the third direction D3 (e.g., FIGS. 5 and 7), the virtual central axis CL may be an axis extending in the third direction D3 while vertically bisecting a line segment in contact with the lower surface of the upper source/drain pattern USD1 and the first interlayer insulating film 110.

As will be described later, the second active contact AC2 is connected to the upper surface of the upper source/drain pattern USD1. In other words, because the first active contact AC1 is not connected to the first side SW1_LSD1 of the lower source/drain pattern LSD1 like the lower source/drain pattern LSD1, in the case of the upper source/drain pattern USD1, the first side surface SW1_USD1 is not etched to form the dummy contact 112. Accordingly, the upper source/drain pattern USD1 may have a symmetrical shape with the first side SW1_USD1 and the second side SW2_USD1 located on both sides in the first direction D1.

In some example embodiments, in a cross-sectional view of the upper source/drain pattern USD1 cut in the first direction D1 and the third direction D3 (e.g., FIGS. 5 and 7), in the upper source/drain pattern USD1, the first distance W_SW1_USD1 to the first side SW1_USD1 may be less than or equal to the second distance W_SW2_USD1 to the second side SW2_USD1. Alternatively, the first distance W_SW1_USD1 of the upper source/drain pattern USD1 to the first side SW1_USD1 may be greater than or equal to the second distance W_SW2_USD1 to the second side SW2_USD1. Alternatively, the first distance W_SW1_USD1 of the upper source/drain pattern USD1 to the first side SW1_USD1 may be equal or substantially equal to the second distance W_SW2_USD1 to the second side SW2_USD1.

Here, the first distance W_SW1_USD1 to the first side SW1_USD1 of the upper source/drain pattern USD1 may be defined as the longest distance among the distances in the first direction D1 from the virtual central axis CL to the first side SW1_USD1. In some example embodiments, the first distance W_SW1_USD1 to the first side SW1_USD1 of the upper source/drain pattern USD1 may be the distance in the first direction D1 from the center point in the third direction D3 of the upper source/drain pattern USD1 to the first side SW1_USD1.

The second distance W_SW2_USD1 to the second side SW2_USD1 of the upper source/drain pattern USD1 may be defined as the longest distance among the distances in the first direction D1 from the virtual central axis CL to the second side SW2_USD1. In some example embodiments, the second distance W_SW2_USD1 from the second side SW2_USD1 of the upper source/drain pattern USD1 may be a distance in the first direction D1 from the middle point of the third direction D3 of the upper source/drain pattern USD1 to the second side SW2_USD1.

As described above, in the case of the lower source/drain pattern LSD1, the first distance W_SW1_LSD1 to the first side SW1_LSD1 is smaller than the second distance W_SW2_LSD1 to the second side SW2_LSD1, and for the upper source/drain pattern USD1, the first distance W_SW1_USD1 to the first side SW1_USD1 is equal or substantially equal to the second distance W_SW2_USD1 to the second side SW2_USD1, e.g. in the case of the lower source/drain pattern LSD1, the first side SW1_LSD1 is etched to form the dummy contact 112, and thus the widths W_SW1_LSD1+W_SW2_LSD1 of the lower source/drain pattern LSD1 in the first direction D1 may be smaller than the widths W_SW1_USD1+W_SW2_USD1 of the drain pattern USD1 in the first direction D1.

For example, the first side SW1_USD1 and the second side SW2_USD1 of the upper source/drain pattern USD1 may have a convex shape toward the outside of the upper source/drain pattern USD1. In other words, the first side SW1_USD1 and the second side SW2_USD1 of the upper source/drain pattern USD1 may have a convex shape in the first direction D1 toward the second interlayer insulating film 120.

Since the first side SW1_USD1 and the second side SW2_USD1 of the upper source/drain pattern USD1 are not connected to the second active contact AC2, and thus the first side SW1_USD1 and the second side SW2_USD1 of the upper source/drain pattern USD1 are not etched to form the dummy contact 112, the first side SW1_USD1 and the second side SW2_USD1 of the upper source/drain pattern USD1 may have a convex shape toward the outside of the upper source/drain pattern USD1 according to the original shape formed according to the selective epitaxial growth method.

A second etch stop layer ESL2 may be located on the upper source/drain pattern USD1. In some example embodiments, the second etch stop layer ESL2 may cover the upper source/drain pattern USD1.

The second etch stop layer ESL2 may cover the first side SW1_USD1 and the second side SW2_USD1 of the upper source/drain pattern USD1. The second etch stop layer ESL2 may not be located between the upper source/drain pattern USD1 and the second active contact AC2. The second etch stop layer ESL2 may cover at least a portion of the upper surface of the upper source/drain pattern USD1. For example, the second active contact AC2 may be connected to the middle region of the upper surface of the upper source/drain pattern USD1 in the first direction D1, and the second etch stop layer ESL2 may cover the left or right region in the first direction D1 that is not connected to the second active contact AC2 on the upper surface of the upper source/drain pattern USD1.

A second interlayer insulating film 120 may be located on the second etch stop layer ESL2. The second interlayer insulating film 120 may cover the upper source/drain pattern USD1. The upper surface of the second interlayer insulating film 120 may be coplanar or substantially coplanar with the upper surface of each of the first and second active contacts AC1 and AC2.

The gate pattern GE may be located on the lower channel pattern LCH1 and the upper channel pattern UCH1. On a plane, the gate pattern GE may have a bar shape extending in the first direction D1. The gate pattern GE may be overlapped with the stacked lower channel pattern LCH1 and upper channel pattern UCH1 in the third direction D3.

The gate pattern GE may extend in the third direction D3 from the upper surface of the isolation layer ST (or the upper surface of the first active pattern AP1) to the gate capping pattern GP. The gate pattern GE may extend in the third direction D3 from the lower channel pattern LCH1 of the first active region AR1 to the upper channel pattern UCH1 of the second active region AR2. Additionally, the gate pattern GE may extend in the third direction D3 from the first semiconductor pattern SP1 at the bottom to the fourth semiconductor pattern SP4 at the top portion.

The gate pattern GE may be located on the upper surface, bottom surface, and both sidewalls of the second semiconductor pattern SP2, the third semiconductor pattern SP3, and the fourth semiconductor pattern SP4, respectively. The gate pattern GE may be located on the upper surface and both sidewalls of the first semiconductor pattern SP1. In other words, the logic cell may include a three-dimensional field effect transistor (e.g., MBCFET or GAAFET) in which the gate pattern GE three-dimensionally surrounds the channel.

The gate pattern GE includes a lower gate pattern LGE1 located within the bottom tier of the FEOL layer, i.e., the first active region AR1, and an upper gate pattern UGE1 located within the top tier of the FEOL layer, i.e., the second active region AR2. The lower gate pattern LGE1 and the upper gate pattern UGE1 may be overlapped with each other in the third direction D3. The lower gate pattern LGE1 and the upper gate pattern UGE1 may be connected to each other. In other words, the gate pattern GE may be a common gate electrode in which the lower gate pattern LGE1 on the lower channel pattern LCH1 and the upper gate pattern UGE1 on the upper channel pattern UCH1 are connected to each other.

The lower gate pattern LGE1 may include a first portion PO1 interposed between the first active pattern AP1 and the first semiconductor pattern SP1, a second portion PO2 interposed between the first semiconductor pattern SP1 and the second semiconductor pattern SP2, and a third portion PO3 interposed between the second semiconductor pattern SP2 and the dummy channel pattern DSP.

The upper gate pattern UGE1 may include a fourth portion PO4 interposed between the dummy channel pattern DSP or seed layer SDL and the third semiconductor pattern SP3, a fifth portion PO5 interposed between the third semiconductor pattern SP3 and the fourth semiconductor pattern SP4, and a sixth portion PO6 located on the fourth semiconductor pattern SP4.

A pair of gate spacers GS may be disposed on both sidewalls of the sixth portion PO6 of the gate pattern GE. The gate spacers GS may extend in the first direction D1 along the gate pattern GE. Upper surfaces of the gate spacers GS may be higher than the upper surfaces of the gate pattern GE. The upper surfaces of the gate spacers GS may be coplanar or substantially coplanar with the upper surface of the second interlayer insulating film 120. The gate spacers GS may include SiCN, SiCON, SiN, or a combination thereof. However, example embodiments are not limited thereto. In some example embodiments, the gate spacers GS may include a multi-layer each including SiCN, SiCON, SiN, or a combination thereof.

A gate capping pattern GP may be located on the upper surface of the gate pattern GE. The gate capping pattern GP may extend in the first direction D1 along the gate pattern GE. In some example embodiments, the gate capping pattern GP may include SiON, SiCN, SiCON, SIN, or a combination thereof. However, example embodiments are not limited thereto.

A gate insulating layer GI may be interposed between the gate pattern GE and the first to fourth semiconductor patterns SP1 to SP4. The gate insulating film GI may include a silicon oxide film, a silicon oxynitride film, a high-k dielectric film, or a combination thereof. However, example embodiments are not limited thereto. In some example embodiments, the gate insulating film GI may include a silicon oxide film directly covering the surfaces of the first to fourth semiconductor patterns SP1 to SP4 and a high-k dielectric film located on the silicon oxide film. In other words, the gate insulating layer GI may include a multi-layer of a silicon oxide layer and a high-k dielectric layer. However, example embodiments are not limited thereto.

The high-k dielectric film may include a high dielectric constant material that has a higher dielectric constant than the silicon oxide film. In some example embodiments, the high dielectric constant material may include hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, and strontium titanium oxide, lithium oxide, aluminum oxide, lead scandium tantalum oxide, lead zinc niobate, or a combination thereof. However, example embodiments are not limited thereto.

The lower gate pattern LGE1 may include a first work function metal pattern located on the first and second semiconductor patterns SP1 and SP2. The upper gate pattern UGE1 may include a second work function metal pattern located on the third and fourth semiconductor patterns SP3 and SP4. Each of the first and second work function metal patterns may include a metal including titanium (Ti), tantalum (Ta), aluminum (Al), tungsten (W), molybdenum (Mo), or a combination thereof, and nitrogen (N). However, example embodiments are not limited thereto. The first and second work function metal patterns may have different work functions. The gate pattern GE may include, for example a low-resistance metal including tungsten (W), ruthenium (Ru), aluminum (Al), titanium (Ti), tantalum (Ta), or a combination thereof on the first and second work function metal patterns. However, example embodiments are not limited thereto. For example, the sixth portion PO6 may include a low-resistance metal.

In some example embodiments, the gate cutting pattern GCP may penetrate the gate pattern GE. The gate pattern GE may be separated from another gate pattern GE adjacent to it in the first direction D1 by the gate cutting pattern GCP. The gate cutting pattern GCP may include an insulating material, for example, a silicon oxide film, a silicon nitride film, or a combination thereof. However, example embodiments are not limited thereto.

The first active contact AC1 may be connected to the lower source/drain pattern LSD1. The second active contact AC2 may be connected to the upper source/drain pattern USD1.

In some example embodiments, the first active contact AC1 may penetrate the second interlayer insulating film 120, the second etch stop layer ELS2, and the first interlayer insulating film 110 and be connected to the lower source/drain pattern LSD1. The first active contact AC1 may be connected to the first side SW1_LSD1 of the lower source/drain pattern LSD1. The first active contact AC1 may not be connected to the upper surface and the second side surface SW2_LSD1 of the lower source/drain pattern LSD1.

The first active contact AC1 may have a lower contact part BAC1 and an upper contact part UAC1.

The lower contact portion BAC1 may extend from the first side SW1_LSD1 of the lower source/drain pattern LSD1 in the first direction D1. One end of the lower contact portion BAC1 in the first direction D1 may be connected to the first side SW1_LSD1 of the lower source/drain pattern LSD1, and the other end of the lower contact part BAC1 in the first direction D1 may be connected to the upper contact part UAC1. As described above, when forming the dummy contact 112, the first side SW1_LSD1 of the lower source/drain pattern LSD1 is etched, and thus the first side SW1_LSD1 of the lower source/drain pattern LSD1 has a flat shape, and the flat surface of the first side SW1_LSD1 may contact the lower contact portion BAC1 of the first active contact AC1.

In addition, by etching the first side SW1_LSD1 of the lower source/drain pattern LSD1 and forming the dummy contact 112 using a side epitaxial growth process, the lower contact portion BAC1 formed by removing the dummy contact 112 and filling it with metal may also have a similar shape to the dummy contact 112 formed using a lateral epitaxial growth process. In some example embodiments, the width of the lower contact portion BAC1 in the third direction D3 may become smaller as it moves away from the first side SW1_LSD1 of the lower source/drain pattern LSD1 in the first direction D1. For example, the width W_MAX_BAC1 of the lower contact portion BAC1 in the third direction D3 at a point closer to the lower source/drain pattern LSD1 in the first direction D1 may be greater than the width W_MIN_BAC1 of the lower contact portion BAC1 in the third direction D3 at a point farther from the lower source/drain pattern LSD1 in the first direction D1.

Here, the point closer to the lower source/drain pattern LSD1 in the first direction D1 may be, for example, a point in contact with the first side SW1_LSD1 of the lower source/drain pattern LSD1, and the point farther from the lower source/drain pattern LSD1 in the first direction D1 may be, for example, a point in contact with the upper contact portion UAC1 of the first active contact AC1.

In some example embodiments, the width W_MAX_BAC1 of the lower contact portion BAC1 in the third direction D3 at the point closest to the lower source/drain pattern LSD1 in the first direction D1 may be at or near a maximum width, and the width W_MIN_BAC1 of the lower contact portion BAC1 in the third direction D3 at the point farthest from the lower source/drain pattern LSD1 in the first direction D1 may be at or near a minimum width. Accordingly, in the cross-sectional view of the lower source/drain pattern LSD1 cut in the first direction D1 and the third direction D3 (e.g., FIGS. 5 and 7), the lower contact portion BAC1 may have a reclining trapezoidal shape.

The upper contact portion UAC1 may be connected to the other end of the lower contact portion BAC1 in the first direction D1. The upper contact portion UAC1 may extend in the third direction D3 through the first interlayer insulating film 110, the second etch stop layer ELS2, and the second interlayer insulating film 120.

The upper contact portion UAC1 may be spaced apart from the lower source/drain pattern LSD1 and the upper source/drain pattern USD1 in the first direction D1. In other words, the upper contact portion UAC1 may not be directly connected to the lower source/drain pattern LSD1, but may be connected to the lower source/drain pattern LSD1 through the lower contact portion BAC1. Additionally, the upper contact portion UAC1 may not be overlapped with the lower channel pattern LCH1 and the upper channel pattern UCH1 in the second direction D2.

Additionally, the upper contact portion UAC1 does not pass through the upper source/drain pattern USD1 when extending in the third direction D3. In other words, the upper contact portion UAC1 is not overlapped with the lower source/drain pattern LSD1 and the upper source/drain pattern USD1 in the third direction D3. Meanwhile, the lower contact portion BAC1 may be connected to the first side SW1_LSD1 of the lower source/drain pattern LSD1, and the first side SW1_USD1 of the upper source/drain pattern USD1 may be partially overlapped in the third direction D3.

The distance W_SW1_LSD1+W_BAC1 from the center point of the lower source/drain pattern LSD1 in the first direction D1 to the farthest point in the first direction D1 from the lower source/drain pattern LSD1 of the lower contact portion BAC1 may be greater than the distance W_SW1_USD1 from the center point in the first direction D1 of the upper source/drain pattern USD1 to the first side SW1_USD1 of the upper source/drain pattern USD1.

Here, the distance W_SW1_LSD1+W_BAC1 from the center point of the lower source/drain pattern LSD1 in the first direction D1 to the farthest point from the lower source/drain pattern LSD1 of the lower contact portion BAC1 in the first direction D1 may be the distance from the virtual central axis CL of the lower source/drain pattern LSD1 to the other end of the lower contact portion BAC1 in the first direction D1, and the distance W_SW1_USD1 from the center point of the first direction D1 of the upper source/drain pattern USD1 to the first side SW1_USD1 of the upper source/drain pattern USD1 may be, for example, the first distance W_SW1_USD1 to the first side SW1_USD1 of the upper source/drain pattern USD1.

Accordingly, the upper contact portion UAC1 connected to the other end of the lower contact portion BAC1 in the first direction D1 does not pass through the upper source/drain pattern USD1 when extended in the third direction D3, and the lower source/drain pattern LSD1 and the upper source/drain pattern USD1 may not be overlapped in the third direction D3.

The first and second active contacts AC1 and AC2 may include a doped semiconductor or metal. For example, the metal may include copper (Cu), aluminum (Al), ruthenium (Ru), cobalt (Co), tungsten (W), molybdenum (Mo), or a combination thereof. However, example embodiments are not limited thereto.

The gate contact GC may be electrically connected to the gate pattern GE by penetrating the gate capping pattern GP. The gate contact GC may include a metal, such as copper (Cu), aluminum (Al), ruthenium (Ru), cobalt (Co), tungsten (W), molybdenum (Mo), or combinations thereof. However, example embodiments are not limited thereto.

The third interlayer insulating film 130 may be located on the second interlayer insulating film 120.

The first metal layer M1 may be located in the third interlayer insulating film 130. The first metal layer M1 may include wirings MIL and first and second power wirings POR1 and POR2. The wiring MIL and the first and second power wirings POR1 and POR2 may include metal, such as copper (Cu), aluminum (Al), ruthenium (Ru), cobalt (Co), tungsten (W), molybdenum (Mo), or a combination thereof. However, example embodiments are not limited thereto.

In some example embodiments, the gate contact GC may be directly connected to the wiring MIL. The first active contact AC1 may be connected to the wiring MIL through the first via VI1. The second active contact AC2 may be connected to the wiring MIL through the second via VI2.

Additional metal layers (e.g., M2, M3, or M4, etc.) may be stacked on the first metal layer M1. The first metal layer M1 and the metal layers (e.g., M2, M3, or M4) on the first metal layer M1 may form a back end of line (BEOL) layer of the semiconductor device. The metal layers (e.g., M2, M3, or M4) on the first metal layer M1 may include routing wires for connecting logic cells to each other.

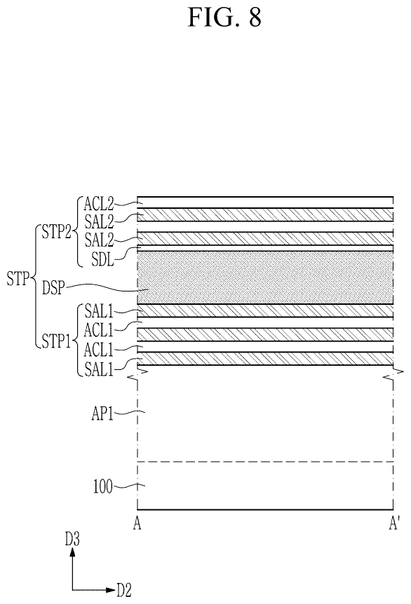

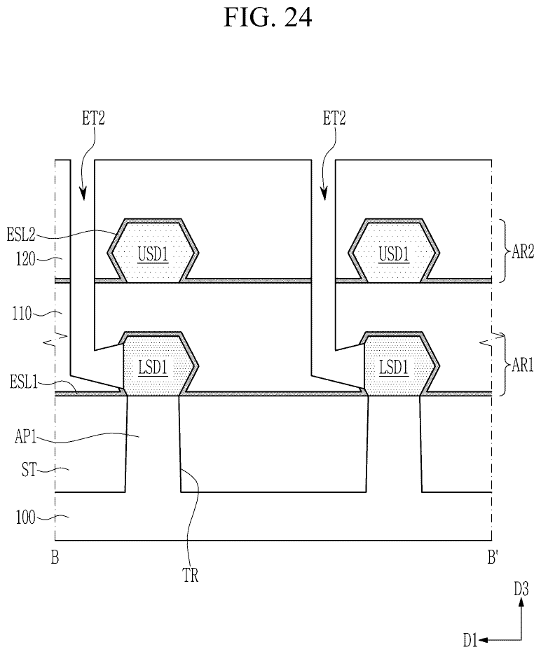

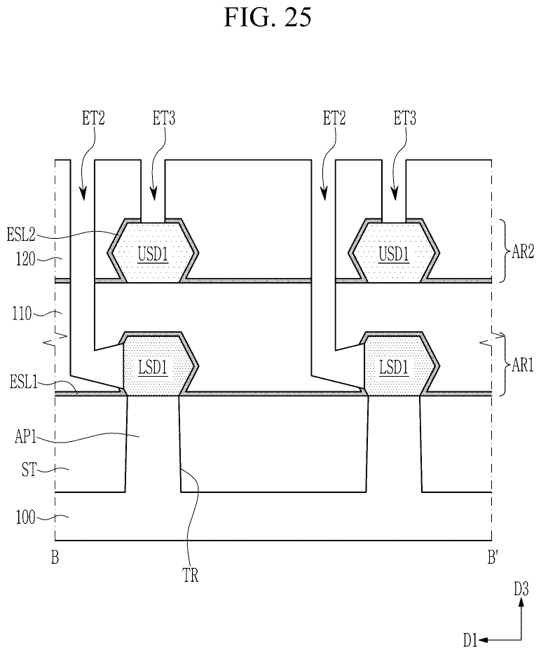

Next, a method of manufacturing a semiconductor device according to some example embodiments will be described with reference to FIGS. 8 to 29. In addition, FIGS. 3 to 7 described above may also be referred to.

FIGS. 8 to 29 are cross-sectional views showing a method of manufacturing a semiconductor device according to a process sequence according to embodiments.

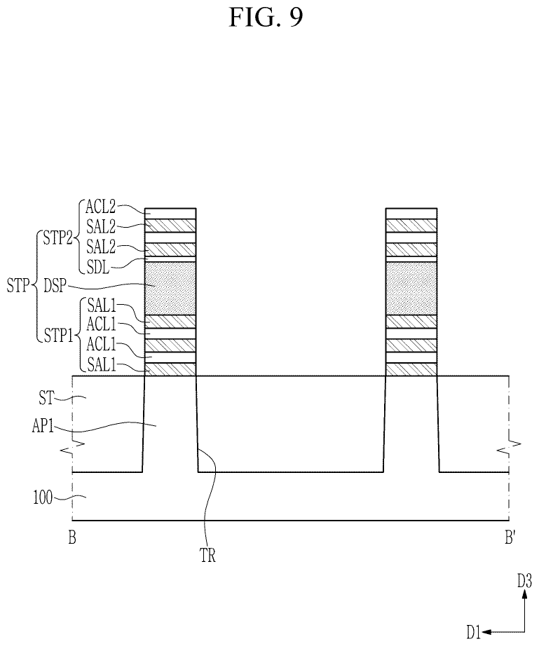

FIG. 8 is a cross-sectional view taken along line A-A′ in FIG. 3. FIG. 9 is a cross-sectional view taken along line B-B′ in FIG. 3. At this time, the cross-sectional view taken along line C-C′ of FIG. 3 may be the same as that of FIG. 9, and thus it is omitted.

Referring to FIGS. 8 and 9, first sacrificial layers SAL1 and first active layers ACL1 may be alternately stacked on the substrate 100. The first sacrificial layers SAL1 may include one of silicon (Si), germanium (Ge), or silicon germanium (SiGe), and the first active layers ACL1 may include silicon (Si), germanium (Ge), or silicon germanium (SiGe). However, example embodiments are not limited thereto. For example, the first sacrificial layers SAL1 may include silicon germanium (SiGe), and the first active layers ACL1 may include silicon (Si). The concentration of germanium (Ge) in each of the first sacrificial layers SAL1 may be 10 at % to 30 at %.

A separation layer may be formed on the uppermost first sacrificial layer SAL1. For example, the length of the separation layer in the third direction D3 may be greater than the length of the first sacrificial layer SAL1 in the third direction D3. The separation layer may include silicon (Si) or silicon germanium (SiGe). However, example embodiments are not limited thereto. When the separation layer includes silicon germanium (SiGe), a concentration of germanium (Ge) in the separation layer may be greater than a concentration of germanium (Ge) in the first sacrificial layer SAL1. For example, the concentration of germanium (Ge) in the separation layer may be about 40 at % to about 90 at %.

A seed layer SDL may be formed on the separation layer. The seed layer SDL may include the same material as the first active layer ACL1. Second sacrificial layers SAL2 and second active layers ACL2 may be alternately stacked on the seed layer SDL. In some example embodiments, each of the second sacrificial layers SAL2 may include the same material as the first sacrificial layer SAL1, and each of the second active layers ACL2 may include the same material as the first active layer ACL1. The separation layer may be interposed between the first sacrificial layer SAL1 and the seed layer SDL.

The stacked first and second sacrificial layers SAL1 and SAL2, first and second active layers ACL1 and ACL2, and separation layer may be patterned to form a stacked pattern STP. The stacked pattern STP may be formed by forming a hardmask pattern on the uppermost second active layer ACL2, and etching the stacked films SAL1, SAL2, ACL1, ACL2, and SDL on the substrate 100 using the hardmask pattern as an etch mask. While the stacked pattern STP is being formed, the upper portion of the substrate 100 may be patterned to form a trench TR defining the first active pattern AP1. The stacked pattern STP may have a bar shape extending in the second direction D2.

The stacked pattern STP includes a lower stacked pattern STP1 on the first active pattern AP1, an upper stacked pattern STP2 on the lower stacked pattern STP1, and a dummy channel pattern DSP between the lower and upper stacked patterns STP1 and STP2. The lower stacked pattern STP1 may include first sacrificial layers SAL1 and first active layers ACL1 that are alternately stacked. The upper stacked pattern STP2 may include a seed layer SDL, second sacrificial layers SAL2 and second active layers ACL2 alternately stacked on the seed layer SDL.

A device isolation layer ST may be formed on the substrate 100 to fill the trench TR. In some example embodiments, an insulating film may be formed on the entire surface of the substrate 100 to cover the first and second active patterns AP1 and AP2 and the stacked patterns STP. The device isolation layer ST may be formed by recessing the insulating layer until the stacked patterns STP are exposed.

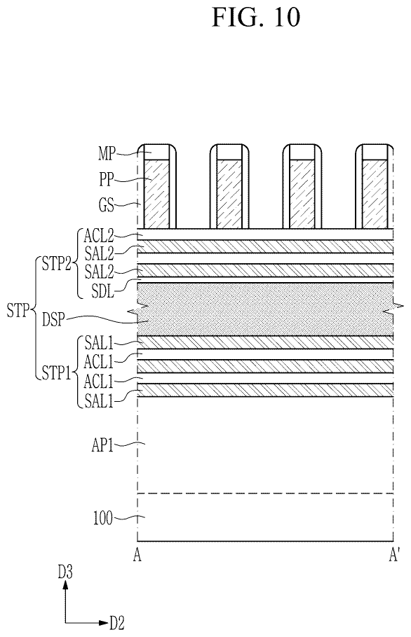

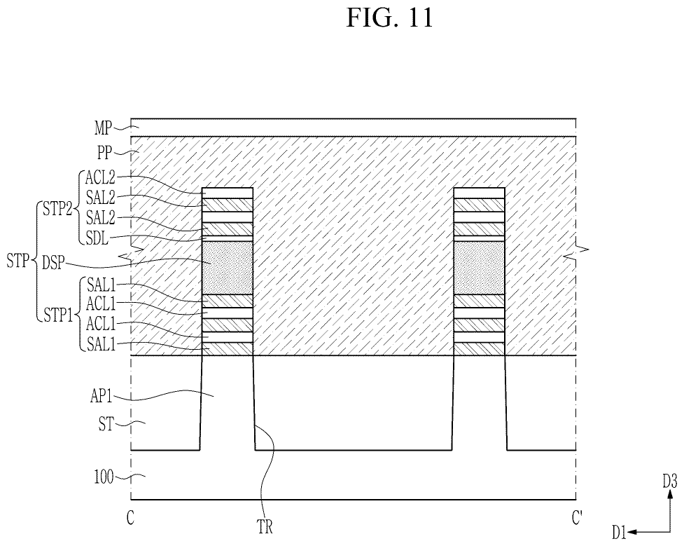

FIG. 10 is a cross-sectional view taken along line A-A′ in FIG. 3. FIG. 11 is a cross-sectional view taken along line C-C′ of FIG. 3. At this time, the cross-sectional view taken along line B-B′ of FIG. 3 may be the same as that of FIG. 9, and thus it is omitted.

Referring to FIGS. 10 and 11, a plurality of sacrificial patterns PP may be formed across the stacked pattern STP. Each sacrificial pattern PP may be formed in a line shape extending in the first direction D1. For example, the sacrificial pattern PP may be formed by forming a sacrificial film on the entire surface of the substrate 100, forming a hardmask pattern MP on the sacrificial film, and patterning the sacrificial film using the hardmask pattern MP as an etch mask. The sacrificial layer may include amorphous silicon or polysilicon. However, example embodiments are not limited thereto.

A pair of gate spacers GS may be formed on both sidewalls of the sacrificial pattern PP, respectively. In some example embodiments, a spacer film may be formed conformally on the entire surface of the substrate 100. The spacer film may cover the sacrificial pattern PP and the hardmask pattern MP. For example, the spacer film may include SiCN, SiCON, SiN, or a combination thereof. However, example embodiments are not limited thereto. Gate spacers GS may be formed by anisotropically etching the spacer film.

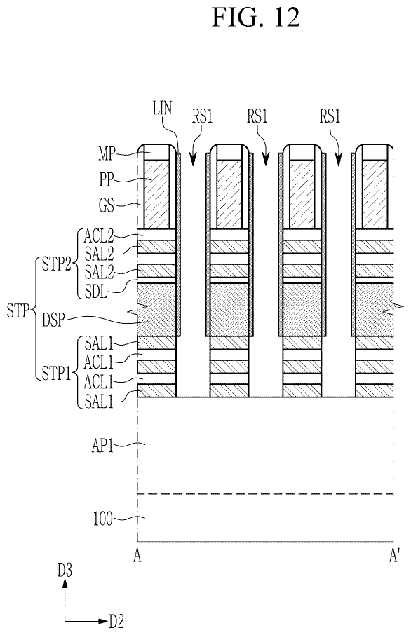

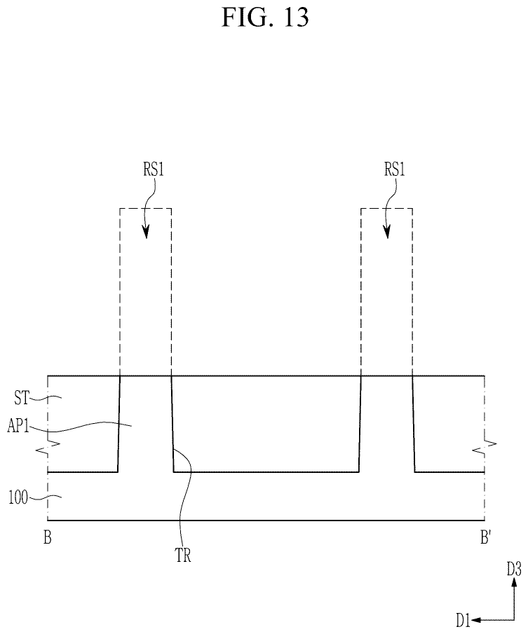

FIG. 12 is a cross-sectional view taken along line A-A′ of FIG. 3. FIG. 13 is a cross-sectional view taken along line B-B′ in FIG. 3. At this time, the cross-sectional view taken along line C-C′ of FIG. 3 may be the same as that of FIG. 11, and thus it is omitted.

Referring to FIGS. 12 and 13, an etching process may be performed on the stacked pattern STP using the gate spacers GS and the hardmask pattern MP as an etch mask. Through an etching process, a first recess RS1 may be formed between the sacrificial patterns PP.

For example, if the dummy channel pattern DSP includes silicon germanium (SiGe), the dummy channel pattern DSP may be replaced with a silicon-based insulating material. The dummy channel pattern DSP exposed by the first recess RS1 may be selectively removed, and a silicon-based insulating material (e.g., silicon nitride) may be filled in the area where the dummy channel pattern DSP has been removed.

Liner films LIN may be formed on both sidewalls of the upper stacked pattern STP2, respectively. The liner films LIN may reduce or prevent the upper stacked pattern STP2 from being exposed by the first recess RS1. The liner films LIN may also cover the dummy channel pattern DSP. The liner films LIN may expose the lower stacked pattern STP1. In some example embodiments, the liner films LIN may include silicon nitride. However, example embodiments are not limited thereto.

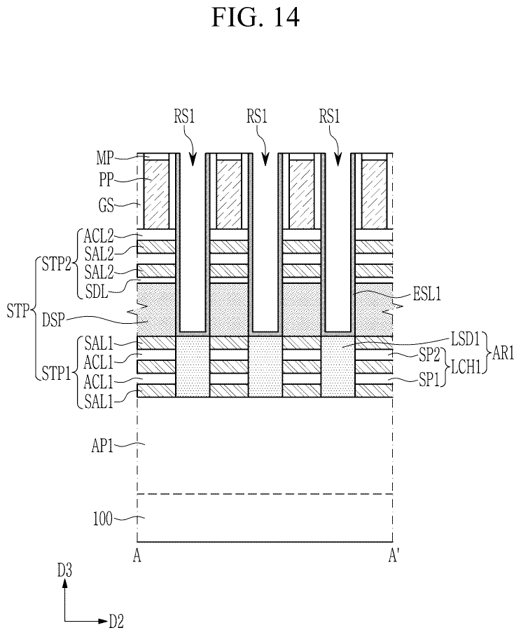

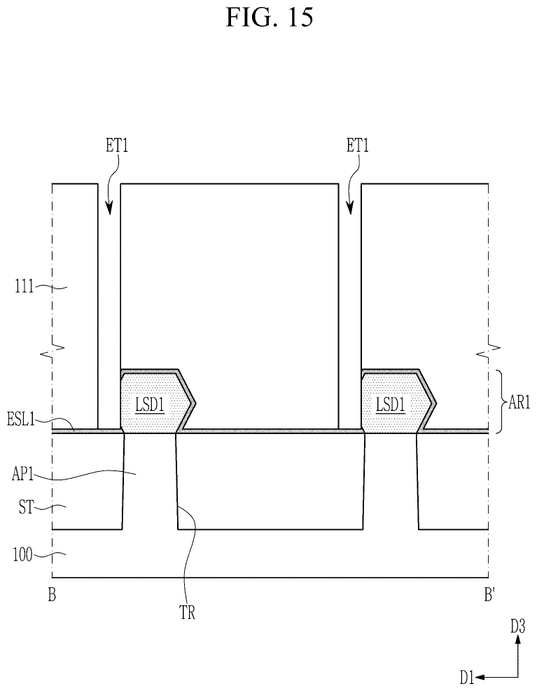

FIG. 14 is a cross-sectional view taken along line A-A′ in FIG. 3. FIGS. 15 and 16 are cross-sectional views taken along line B-B′ in FIG. 3. At this time, the cross-sectional view taken along line C-C′ of FIG. 3 may be the same as that of FIG. 11, and thus it is omitted.

Referring to FIG. 14, a lower source/drain pattern LSD1 may be formed in the first recess RS1. In some example embodiments, a selective epitaxial growth SEG process is performed using the exposed sidewall of the lower stacked pattern STP1 and the upper surface of the first active pattern AP1 as a seed layer, thereby forming the lower source/drain pattern LSD1. The lower source/drain pattern LSD1 may be grown using the first active layers ACL1 and the first active pattern AP1 exposed by the first recess RS1 as seeds. In some example embodiments, the selective epitaxial growth SEG process may include a chemical vapor deposition (CVD) process or a molecular beam epitaxy (MBE) process. However, example embodiments are not limited thereto.

During a selective epitaxial growth (SEG) process, impurities may be implanted in-situ into the lower source/drain pattern LSD1. As another example, after the lower source/drain pattern LSD1 is formed, impurities may be injected into the lower source/drain pattern LSD1. The lower source/drain pattern LSD1 may be doped to have a first conductivity type (e.g., P-type).

A sidewall of the upper stacked pattern STP2 may be covered by a liner film LIN. In other words, the second active layers ACL2 of the upper stacked pattern STP2 may not be exposed by the liner layer LIN during the selective epitaxial growth (SEG) process. Therefore, a separate semiconductor layer may not be grown on the upper stacked pattern STP2 during the selective epitaxial growth (SEG) process.

The first active layers ACL1 interposed between a pair of lower source/drain patterns LSD1 may form the lower channel pattern LCH1. That is, the first and second semiconductor patterns SP1 and SP2 of the lower channel pattern LCH1 may be formed from the first active layers ACL1. The lower channel pattern LCH1 and the lower source/drain pattern LSD1 may form the first active region AR1, which is the bottom tier of the 3D device.

The liner film LIN may be selectively removed, and the first etch stop layer ESL1 may be conformally formed in the first recess RS1. The first etch stop layer ESL1 may cover the lower source/drain pattern LSD1.

Referring to FIG. 15, a filling film 111 is formed in the first recess RS1, a hardmask pattern is formed on the filling film 111, and the filling film 111 is patterned using the hardmask pattern as an etch mask to from a first empty space ET1. For example, patterning may be performed using a dry etching process. One side of the lower source/drain pattern LSD1 in the first direction D1 and a portion of the first etch stop layer ESL1 are etched by the first empty space ET1. The first empty space ET1 may not be overlapped with the lower stacked pattern STP1 and the upper stacked pattern STP2 in the second direction D2.

Referring to FIG. 16, the filling film 111 is removed, and a dummy contact 112 is formed on one side of the etched lower source/drain pattern LSD1 in the first direction D1.

In some example embodiments, the dummy contact 112 may use a lateral epitaxial growth (EPI lateral growth) process. The dummy contact 112 may be formed by performing a lateral epitaxial growth process using one side of the etched lower source/drain pattern LSD1 in the first direction D1 as a seed layer. In some example embodiments, the lateral epitaxial growth process may include a chemical vapor deposition (CVD) process or a molecular beam epitaxy (MBE) process. However, example embodiments are not limited thereto.

At this time, the dummy contact 112 may have a composition different from that of the lower source/drain pattern LSD1. For example, when the lower source/drain pattern LSD1 includes silicon germanium (SiGe), the dummy contact 112 may include silicon (Si). Alternatively, if the dummy contact 112 also includes silicon germanium (SiGe), the concentration of germanium (Ge) in the dummy contact 112 may be different from that of the lower source/drain pattern LSD1. For example, the concentration of the germanium (Ge) of the lower source/drain pattern LSD1 may be about 10 at % to about 30 at %, and the concentration of the germanium (Ge) of the dummy contact 112 may be about 40 at % to about 90 at %. Accordingly, when removing the dummy contact 112, which will be described later, the lower source/drain pattern LSD1 is not removed, and the dummy contact 112 can be selectively removed.

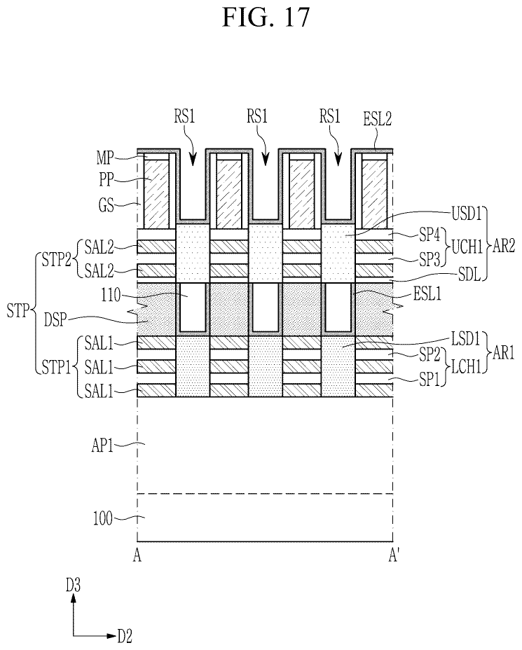

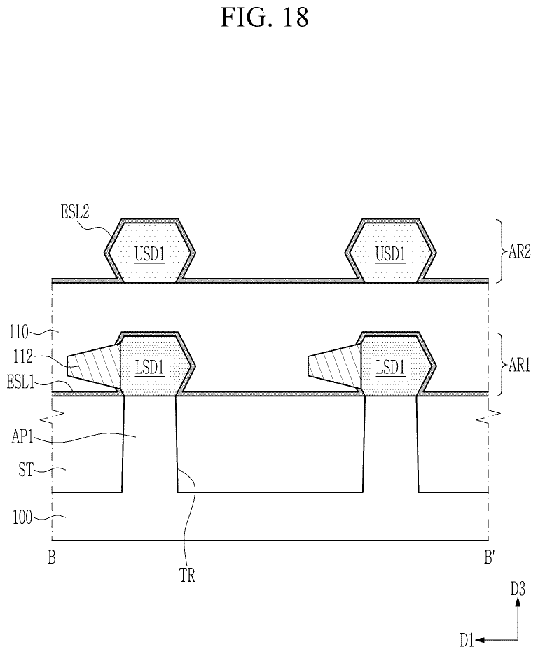

FIG. 17 is a cross-sectional view taken along line A-A′ in FIG. 3. FIG. 18 is a cross-sectional view taken along line B-B′ in FIG. 3. At this time, the cross-sectional view taken along line C-C′ of FIG. 3 may be the same as that of FIG. 11, and thus it is omitted.

Referring to FIGS. 17 and 18, the first interlayer insulating film 110 may be formed in the first recess RS1. In some example embodiments, the first interlayer insulating film 110 may fill the first recess RS1 to a height that covers the dummy channel pattern DSP. A portion of the first etch stop layer ESL1 is removed within the first recess RS1 where the first interlayer insulating film 110 is not formed. As a result, both sidewalls of the upper stacked pattern STP2 may be exposed by the first recess RS1.

An upper source/drain pattern USD1 may be formed between the upper stacked patterns STP2 in the first recess RS1. In some example embodiments, the upper source/drain pattern USD1 may be formed by performing a selective epitaxial growth (SEG) process using the exposed sidewall of the upper stacked pattern STP2 as a seed layer. The upper source/drain pattern USD1 may be grown using the second active layers ACL2 and the seed layer SDL exposed by the first recess RS1 as seeds. In some example embodiments, the selective epitaxial growth (SEG) process may include a chemical vapor deposition (CVD) process or a molecular beam epitaxy (MBE) process. However, example embodiments are not limited thereto.

During the selective epitaxial growth (SEG) process, impurities may be implanted in-situ into the upper source/drain pattern USD1. As another example, after the upper source/drain pattern USD1 is formed, impurities may be injected into the upper source/drain pattern USD1. The upper source/drain pattern USD1 may be doped to have a second conductivity type (e.g., N-type) that is different from the first conductivity type (e.g., P-type) of the lower source/drain pattern LSD1.

The second active layers ACL2 interposed between a pair of upper source/drain patterns USD1 may form an upper channel pattern UCH1. That is, the third and fourth semiconductor patterns SP3 and SP4 of the upper channel pattern UCH1 may be formed from the second active layers ACL2. The upper channel patterns UCH1 and the upper source/drain pattern USD1 may form the second active region AR2, which is the upper tier of the three-dimensional device.

The second etch stop layer ESL2 may be conformally formed in the first recess RS1. The second etch stop layer ESL2 may cover the upper source/drain pattern USD1.

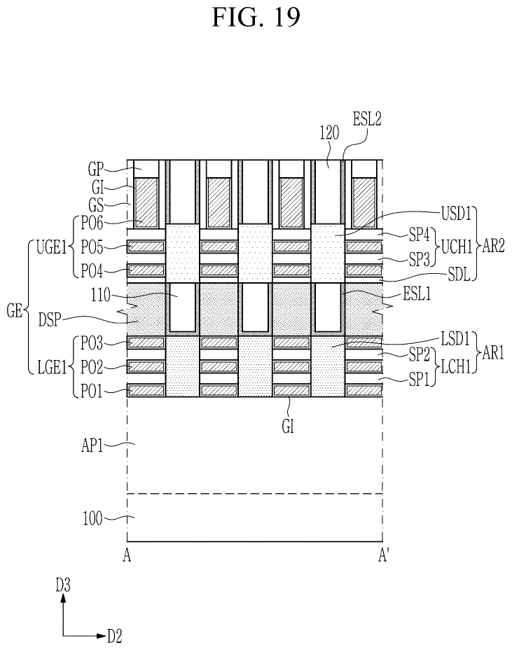

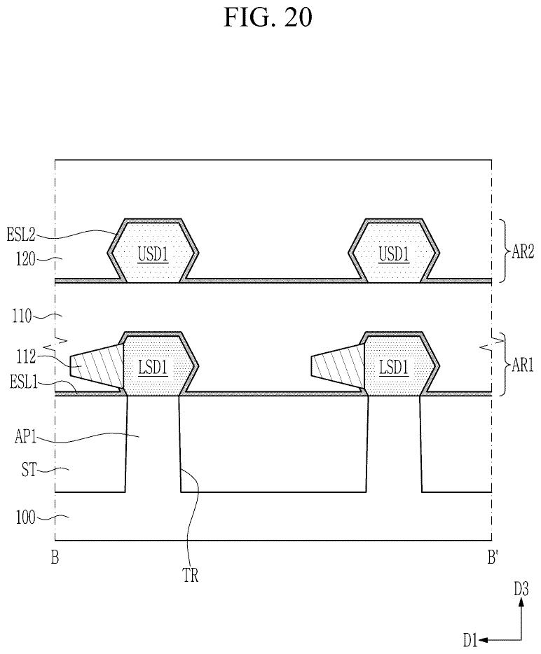

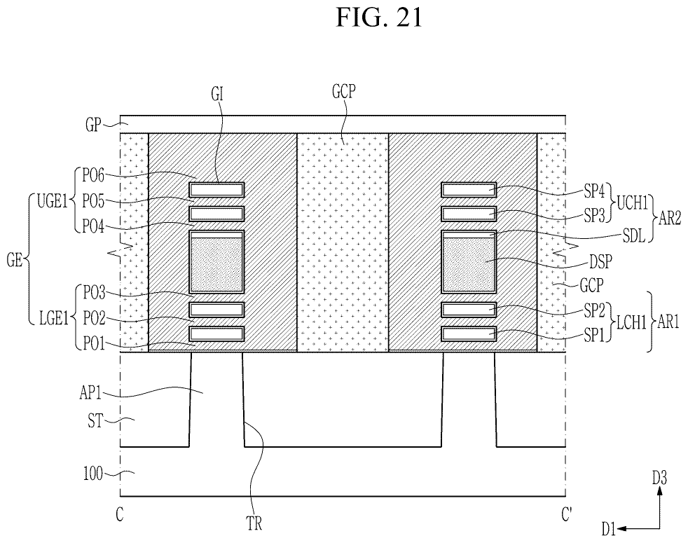

FIG. 19 is a cross-sectional view taken along line A-A′ of FIG. 3. FIG. 20 is a cross-sectional view taken along line B-B′ in FIG. 3. FIG. 21 is a cross-sectional view taken along line C-C′ of FIG. 3.

Referring to FIGS. 19 to 21, a second interlayer insulating film 120 may be formed on the second etch stop layer ESL2. In some example embodiments, the second interlayer insulating film 120 may include a silicon oxide film. However, example embodiments are not limited thereto.

The second interlayer insulating film 120 may be planarized until the upper surface of the sacrificial pattern PP is exposed. Planarization of the second interlayer insulating film 120 may be performed using an etch back or chemical mechanical polishing (CMP) process. During the planarization process, the hardmask pattern MP may be completely removed. As a result, the upper surface of the second interlayer insulating film 120 may be coplanar or substantially coplanar with the upper surface of the sacrificial pattern PP and the upper surfaces of the gate spacers GS.

A gate cutting pattern GCP that penetrates the sacrificial pattern PP may be formed. The gate cutting pattern GCP may include a silicon oxide film or a silicon nitride film. However, example embodiments are not limited thereto.

The exposed sacrificial pattern PP may be selectively removed. To remove the sacrificial pattern PP, wet etching using an etchant that selectively etch polysilicon can be used. By removing the sacrificial pattern PP, the first and second sacrificial layers SAL1 and SAL2 may be exposed.

An etching process is performed to selectively etch the first and second sacrificial layers SAL1 and SAL2, and the first and second sacrificial layers SAL1 and SAL2 may be removed while leaving the first to fourth semiconductor patterns SP1 to SP4 and the dummy channel pattern DSP intact. The etching process can have a high etch rate for silicon germanium. For example, an etch process may have a high etch rate for silicon germanium with a germanium concentration greater than 10 at %.

The gate insulating layer GI may be conformally formed in an area where the sacrificial pattern PP and the first and second sacrificial layers SAL1 and SAL2 have been removed. The gate pattern GE may be formed on the gate insulating film Gl. The gate pattern GE may be formed by forming first to fifth portions PO1 to PO5 between the first to fourth semiconductor patterns SP1 to SP4, and a sixth portion PO6 in the area where the sacrificial pattern PP was removed.

The gate pattern GE may be recessed, reducing its height. The gate capping pattern GP may be formed on the recessed gate pattern GE. A planarization process may be performed on the gate capping pattern GP so that the upper surface of the gate capping pattern GP is coplanar or substantially coplanar with the upper surface of the second interlayer insulating film 120.

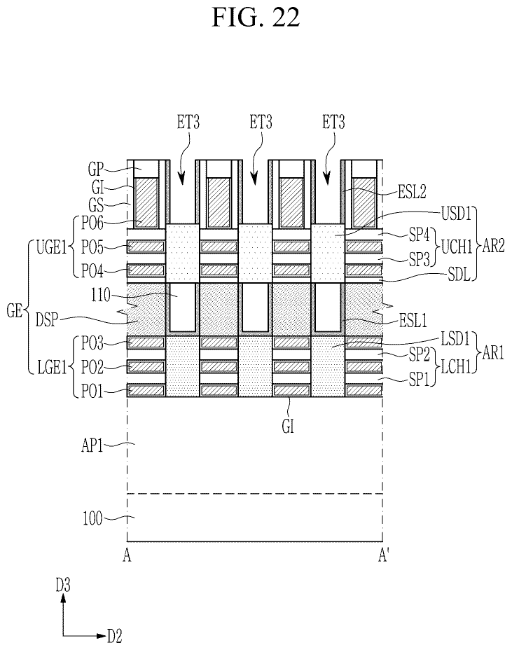

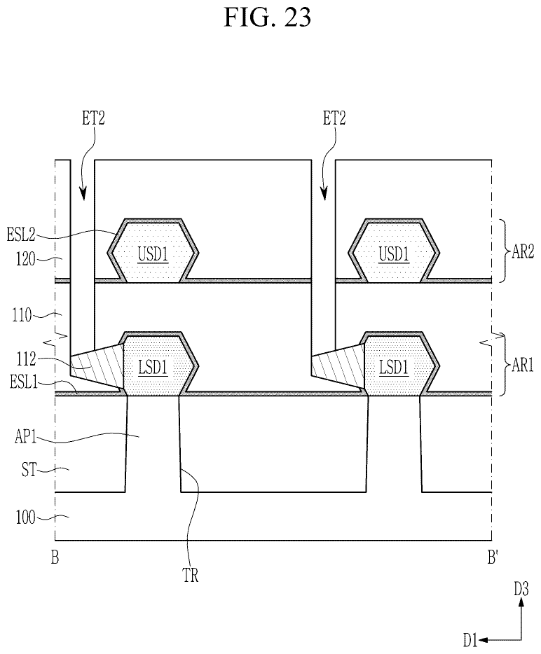

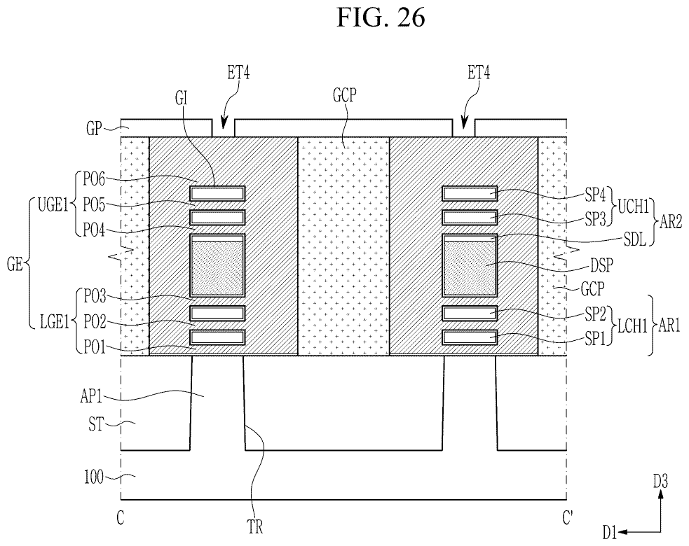

FIG. 22 is a cross-sectional view taken along line A-A′ of FIG. 3. FIGS. 23 to 25 are cross-sectional views taken along line B-B′ in FIG. 3. FIG. 26 is a cross-sectional view taken along line C-C′ of FIG. 3.

Referring to FIGS. 22 to 26, the dummy contact 112 can be removed. In some example embodiments, a hardmask pattern is formed on the second interlayer insulating film 120, and the second interlayer insulating film 120 is patterned using the hardmask pattern as an etch mask to form a second empty space ET2. For example, patterning may be performed using a dry etching process.

The second empty space ET2 may pass through the second interlayer insulating film 120, the second etch stop layer ELS2, and the first interlayer insulating film 110 in the third direction D3 to expose a portion of the upper surface of the dummy contact 112. For example, the second empty space ET2 may be connected to the upper surface of one end of the dummy contact 112 in the first direction D1. The second empty space ET2 may be spaced apart from the lower source/drain pattern LSD1 in the first direction D1. The second empty space ET2 may not be overlapped with the lower channel pattern LCH1 and the upper channel pattern UCH1 in the second direction D2. The second empty space ET2 may not pass through the upper source/drain pattern USD1 when extended in the third direction D3.

The dummy contact 112 may be selectively removed through the second empty space ET2. The dummy contact 112 may be removed using a wet etching process.

Additionally, the second interlayer insulating film 120 is patterned to penetrate the second interlayer insulating film 120 and the second etch stop layer ELS2 in the third direction D3, thereby forming a third empty space ET3 that exposes a portion of the upper surface of the upper source/drain pattern USD1. For example, patterning may be performed using a dry etching process. Additionally, a fourth empty space ET4 is formed that penetrates the gate capping pattern GP in the third direction D3 and exposes a portion of the upper surface of the gate pattern GE.

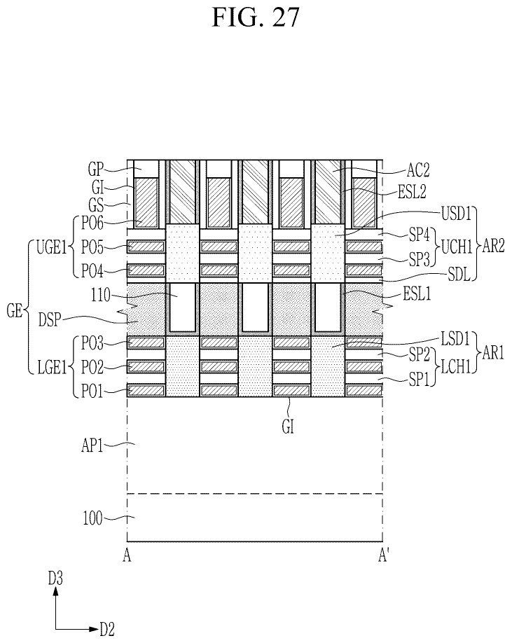

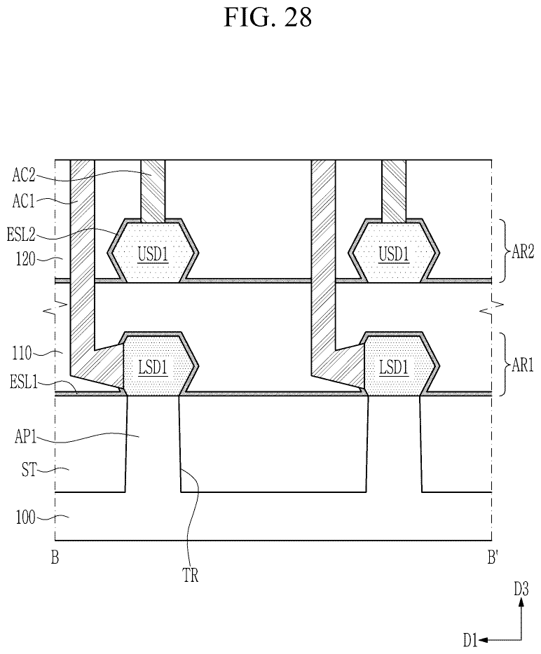

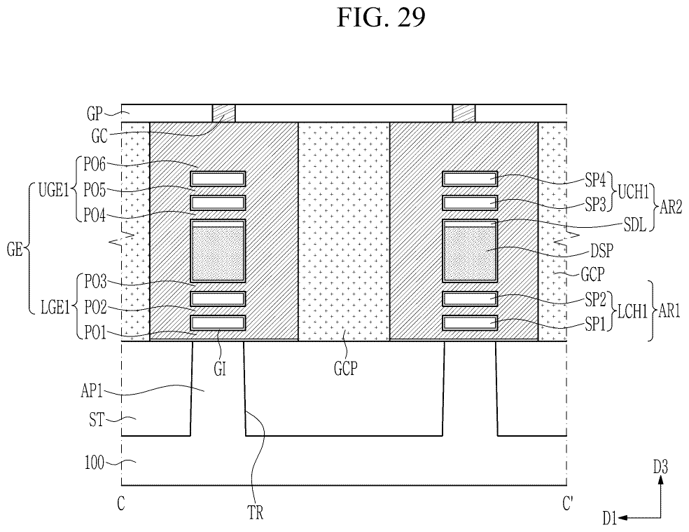

FIG. 27 is a cross-sectional view taken along line A-A′ in FIG. 3. FIG. 28 is a cross-sectional view taken along line B-B′ in FIG. 3. FIG. 29 is a cross-sectional view taken along line C-C′ of FIG. 3.

Referring to FIGS. 27 to 29, the second to fourth empty spaces ET2, ET3, and ET4 are filled with metal to form a first active contact AC1 connected to the lower source/drain pattern LSD1 in the second empty space ET2, to form a second active contact AC2 in the third empty space ET3 connected to the upper source/drain pattern USD1, and to form a gate contact GC connected to the gate pattern GE in the fourth empty space ET4.

The first active contact AC1, the second active contact AC2, and the gate contact GC may include a metal, for example, copper (Cu), aluminum (Al), ruthenium (Ru), cobalt (Co), tungsten (W), molybdenum (Mo), or a combination thereof. However, example embodiments are not limited thereto.

Referring again to FIGS. 4 to 6, a third interlayer insulating film 130 may be formed on the second interlayer insulating film 120. A first metal layer M1 including wirings MIL may be formed in the third interlayer insulating film 130.

In some example embodiments, the gate contact GC may be directly connected to the wiring MIL. The first active contact AC1 may be connected to the wiring MIL through the first via VI1. The second active contact AC2 may be connected to the wiring MIL through the second via VI2.

While some example embodiments of the present disclosure have been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor device, comprising:
a first active pattern and a second active pattern on a substrate, the first active pattern spaced apart from the second active pattern in a first direction, and extending in a second direction, the second direction being different from the first direction;
a lower channel pattern and a lower source/drain pattern on the first active pattern and alternately arranged in the second direction;
an upper channel pattern on the lower channel pattern, and an upper source/drain pattern on the lower source/drain pattern;
a gate pattern on first active pattern, the lower channel pattern, and the upper channel pattern; and
a first active contact connected to the lower source/drain pattern, and a second active contact connected to the upper source/drain pattern,
wherein the lower source/drain pattern includes an asymmetric shape on a first side and an asymmetric shape on a second side, the first side and the second side being opposite to each other in the first direction, and
the first active contact is connected to the first side of the lower source/drain pattern in the first direction.

2. The semiconductor device of claim 1, wherein
a distance in the first direction from a center point of the lower source/drain pattern to the first side of the lower source/drain pattern is smaller than a distance in the first direction from the center point of the lower source/drain pattern to the second side of the lower source/drain pattern.

3. The semiconductor device of claim 1, wherein
the lower source/drain pattern includes a flat shape on the first side and a convex shape on the second side.

4. The semiconductor device of claim 1, wherein
a first side and a second side of the upper source/drain pattern in the first direction have a symmetrical shape.

5. The semiconductor device of claim 4, wherein
a distance in the first direction from a center point of the upper source/drain pattern to the first side is a same distance as a distance in the first direction from the center point of the upper source/drain pattern to the second side.

6. The semiconductor device of claim 4, wherein
the first side and the second side of the upper source/drain pattern have a convex shape.

7. The semiconductor device of claim 4, wherein
a width of the lower source/drain pattern in the first direction is smaller than a width of the upper source/drain pattern in the first direction.

8. The semiconductor device of claim 1, wherein
the second active contact is connected to an upper surface of the upper source/drain pattern.

9. The semiconductor device of claim 1, wherein
the first active contact is not connected to an upper surface of the lower source/drain pattern, and
the first active contact is not connected to the second side of the lower source/drain pattern.

10. The semiconductor device of claim 1, wherein
the semiconductor device further includes
a first etch stop layer covering the lower source/drain pattern, and
a second etch stop layer covering the upper source/drain pattern.

11. The semiconductor device of claim 10, wherein
the first etch stop layer is not between the lower source/drain pattern and the first active contact, and
the first etch stop layer covers an upper surface and the second side of the lower source/drain pattern.

12. The semiconductor device of claim 10, wherein
the first active contact is connected to a middle region in a third direction of the first side of the lower source/drain pattern, the third direction being different from the first direction and the second direction,
an upper region and a lower region of the lower source/drain pattern in the third direction are not connected to the first active contact on the first side of the lower source/drain pattern, and
the upper region and the lower region of the lower source/drain pattern are covered by the first etch stop layer.

13. The semiconductor device of claim 10, wherein
the second etch stop layer covers the first side and the second side of the upper source/drain pattern,
the second etch stop layer does not cover at least a portion of an upper surface of the upper source/drain pattern, and
the second etch stop layer is not between the upper source/drain pattern and the second active contact.

14. A semiconductor device, comprising:
a first active pattern and a second active pattern on a substrate, the first active pattern spaced apart from the second active pattern in a first direction, and extending in a second direction, the second direction being different from the first direction;
a lower channel pattern and a lower source/drain pattern on the first active pattern and alternately arranged in the second direction;
an upper channel pattern on the lower channel pattern, and an upper source/drain pattern on the lower source/drain pattern;
a gate pattern on the first active pattern, the lower channel pattern, and the upper channel pattern; and
a first active contact connected to the lower source/drain pattern, and a second active contact connected to the upper source/drain pattern,
wherein the first active contact includes
a lower contact portion connected to a first side of the lower source/drain pattern in the first direction, and the lower contact portion extending in the first direction,
an upper contact portion connected to the lower contact portion, and the upper contact portion extending in a third direction, the third direction being different from the first direction and the second direction, and
a width of the lower contact portion in the third direction at a point closer to the lower source/drain pattern in the first direction is greater than a width of the lower contact portion in the third direction at a point further from the lower source/drain pattern in the first direction.

15. The semiconductor device of claim 14, wherein
a width of the lower contact portion in the third direction is at a maximum width at the point closest to the lower source/drain pattern in the first direction, and
a width of the lower contact portion in the third direction is at a minimum width at a farthest point from the lower source/drain pattern in the first direction.

16. The semiconductor device of claim 15, wherein
the lower contact portion has a trapezoidal shape in a cross-sectional view in the first direction and the third direction.

17. The semiconductor device of claim 15, wherein
a distance in the first direction from a center point of the lower source/drain pattern to a farthest point of the lower contact portion is greater than a distance in the first direction from the center point of the upper source/drain pattern in to the first side of the upper source/drain pattern.

18. The semiconductor device of claim 17, wherein
the lower contact portion is at least partially overlapped with one side of the upper source/drain pattern in the first direction in the third direction.

19. The semiconductor device of claim 17, wherein
the upper contact portion is not overlapped with the lower source/drain pattern and the upper source/drain pattern in the third direction.

20. A semiconductor device, comprising
a first active pattern on a substrate, the first active pattern spaced apart from a second active pattern in a first direction, and extending in a second direction, the second direction being different from the first direction;
a lower channel pattern and a lower source/drain pattern on the first active pattern and alternately arranged in the second direction;
an upper channel pattern on the lower channel pattern, and an upper source/drain pattern on the lower source/drain pattern;
a gate pattern on the first active pattern, the lower channel pattern, and the upper channel pattern;
a first active contact connected to the lower source/drain pattern; and
a second active contact connected to the upper source/drain pattern,
wherein the lower source/drain pattern includes an asymmetric shape on a first side and a second side, the first side and the second side being opposite each other in the first direction,
the first active contact includes
a lower contact portion connected to the first side of the lower source/drain pattern in the first direction, and the lower contact portion extending in the first direction,
an upper contact portion connected to the lower contact portion, and the upper contact portion extending in a third direction, the third direction being different from the first direction and the second direction, and
a width of the lower contact portion in the third direction at a point closer to the lower source/drain pattern in the first direction is greater than a width of the lower contact portion in the third direction at a point further from the lower source/drain pattern in the first direction.
